(19) United States
(12) Patent Application Publication
(10) Pub. No.: US 2022/0105828 A1
(43) Pub. Date: Apr. 7, 2022

(54) INFORMATION PROCESSING APPARATUS, INFORMATION PROCESSING SYSTEM, NON-TRANSITORY COMPUTER READABLE MEDIUM, AND AUTONOMOUS VEHICLE

(71) Applicant: TOYOTA JIDOSHA KABUSHIKI KAISHA, Toyota-shi (JP)

(72) Inventors: Makoto MATSUSHITA, Ichinomiya-shi (JP); Tomo SASAKI, Toyota-shi (JP); Yui NAKAMURA, Nagoya-shi (JP); Satoshi KOMAMINE, Nagoya-shi (JP); Shuichi SAWADA, Nagoya-shi (JP); Tatsuya SUZUKI, Nagoya-shi (JP)

(73) Assignee: TOYOTA JIDOSHA KABUSHIKI KAISHA, Toyota-shi (JP)

(21) Appl. No.: 17/493,058

(22) Filed: Oct. 4, 2021

(30) Foreign Application Priority Data
Oct. 2, 2020 (JP) 2020-167934

(51) Int. Cl. B60L 58/13; B60L 58/16; G01R 31/392; G01R 31/367; G01R 31/396

(52) U.S. Cl. CPC B60L 58/13; B60L 58/16; B60Y 2200/60; G01R 31/367; G01R 31/396; G01R 31/392

(57) ABSTRACT

An information processing apparatus for controlling an autonomous vehicle that travels between points includes a controller. The controller is configured to determine, based on the current time and a predetermined time, to charge, to replace, or neither to charge nor replace a battery, mounted in the autonomous vehicle, at a first point when the autonomous vehicle located at the first point is to travel by the predetermined time to a second point that is the next destination.

### CROSS-REFERENCE TO RELATED APPLICATION

This application claims priority to Japanese Patent Application No. 2020-167934, filed on Oct. 2, 2020, the entire contents of which are incorporated herein by reference.

### TECHNICAL FIELD

The present disclosure relates to an information processing apparatus, an information processing system, a program, and an autonomous vehicle.

### BACKGROUND

For example, a system using a plurality of automatic guided vehicles (AGVs) is utilized as a distribution system for conveying goods in factories and plants. For example, patent literature (PTL) 1 discloses a charging control apparatus that charges an AGV before execution of the next conveyance order when an amount of energy sufficient to execute the next conveyance order does not remain in the battery.

### CITATION LIST

### Patent Literature

PTL 1: JP 2000-152421 A

### SUMMARY

Autonomous vehicles that travel from a first point to a distant second point by a predetermined time, unlike AGVs moving in limited areas within factories and plants, can be considered. At this time, if the remaining level of the battery mounted in the autonomous vehicle reaches zero, causing an electricity shortage, then the autonomous vehicle becomes incapable of driving. It thus becomes difficult to travel to the destination.

It would be helpful to provide technology for suppressing an electricity shortage in an autonomous vehicle that travels between points.

An information processing apparatus according to an embodiment of the present disclosure is an information processing apparatus for controlling an autonomous vehicle that travels between points, the information processing apparatus including a controller configured to:

determine, based on a current time and a predetermined time, to charge, to replace, or neither to charge nor replace a battery, mounted in the autonomous vehicle, at a first point when the autonomous vehicle located at the first point is to travel by the predetermined time to a second point that is a next destination.

A program according to an embodiment of the present disclosure is configured to cause an information processing apparatus for controlling an autonomous vehicle that travels between points to execute operations including:

determining, based on a current time and a predetermined time, to charge, to replace, or neither to charge nor replace a battery, mounted in the autonomous vehicle, at a first point when the autonomous vehicle located at the first point is to travel by the predetermined time to a second point that is a next destination.

An autonomous vehicle according to an embodiment of the present disclosure is an autonomous vehicle to be controlled by an information processing apparatus and to travel between points, the autonomous vehicle including a controller configured to:

determine, based on a current time and a predetermined time, to charge, to replace, or neither to charge nor replace a mounted battery at a first point when the autonomous vehicle is to travel by the predetermined time to a second point that is a next destination.

The information processing apparatus, information processing system, program, and autonomous vehicle according to embodiments of the present disclosure can prevent an electricity shortage in an autonomous vehicle that travels between points.

### BRIEF DESCRIPTION OF THE DRAWINGS

In the accompanying drawings:

FIG. 1 is a configuration diagram illustrating a configuration of an information processing system that includes an information processing apparatus according to an embodiment of the present disclosure;

FIG. 2 is a functional block diagram illustrating schematic configurations of the information processing apparatus and an autonomous vehicle of FIG. 1;

FIG. 3 is a sequence diagram for illustrating an example of an information processing method executed by the information processing system of FIG. 1;

FIG. 4 is a flowchart illustrating a first example of an information processing method executed by the information processing apparatus of FIG. 1;

FIG. 5 is a flowchart illustrating a second example of an information processing method executed by the information processing apparatus of FIG. 1;

FIG. 6 is a flowchart illustrating a third example of an information processing method executed by the information processing apparatus of FIG. 1;

FIG. 7 is a flowchart illustrating a fourth example of an information processing method executed by the information processing apparatus of FIG. 1;

FIG. 8 is a diagram for illustrating a first example of processing by a controller of the information processing apparatus of FIG. 2; and

FIG. 9 is a diagram for illustrating a second example of processing by a controller of the information processing apparatus of FIG. 2.

### DETAILED DESCRIPTION

Embodiments of the present disclosure are described below with reference to the drawings.

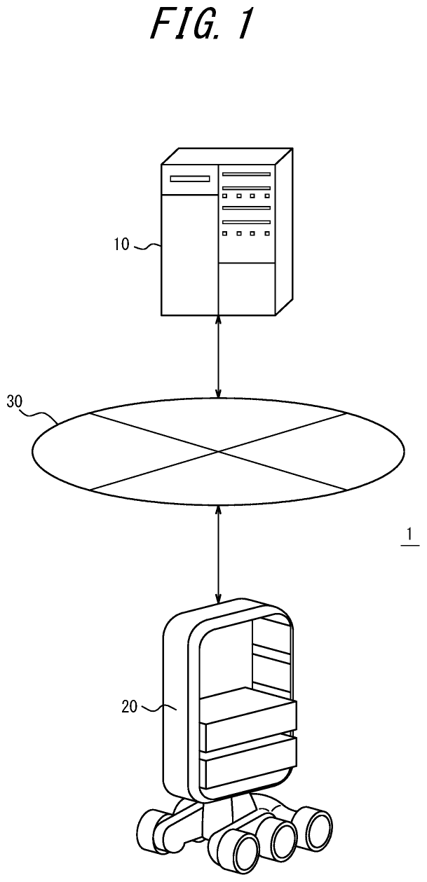

FIG. 1 is a configuration diagram illustrating a configuration of an information processing system 1 that includes an information processing apparatus 10 according to an embodiment of the present disclosure. With reference to FIG. 1, an overview of the information processing system 1 that includes the information processing apparatus 10 according to an embodiment of the present disclosure is primarily described. In addition to the information processing apparatus 10, the information processing system 1 includes an autonomous vehicle 20.

In FIG. 1, one each of the information processing apparatus 10 and the autonomous vehicle 20 are illustrated for the sake of simplicity, but the number of information processing apparatuses 10 and autonomous vehicles 20 included in the information processing system 1 may be two or more of each. The information processing apparatus 10 and the autonomous vehicle 20 are each communicably connected to a network 30 including, for example, a mobile communication network and/or the Internet.

The information processing apparatus 10 is, for example, a single server apparatus or a plurality of server apparatuses that can communicate with each other. The information processing apparatus 10 is not limited to being a server apparatus and may be any general purpose electronic device, such as a personal computer (PC) or smartphone, or may be another electronic device dedicated to the information processing system 1. The information processing apparatus 10 controls the autonomous vehicle 20 that travels between points.

The autonomous vehicle 20 includes, for example, any electric vehicle that can drive using a vehicle-mounted battery and travels between points by autonomous driving. The autonomous vehicle 20 includes, for example, a small, unmanned delivery vehicle that autonomously delivers packages. This example is not limiting, and the autonomous vehicle 20 may include any electric vehicle used in applications other than delivery of packages or may include any manned electric vehicle that drives autonomously.

After the autonomous vehicle 20 moves to a predetermined position as a destination, a battery provided in the autonomous vehicle 20 itself is charged as necessary using a battery charging facility if such a charging facility is provided at the predetermined point, for example. Similarly, the battery provided in the autonomous vehicle 20 itself is replaced with a charged battery provided in a battery replacement facility if such a replacement facility is provided at the predetermined point, for example.

As a summary of an embodiment, the information processing apparatus 10 determines, based on the current time and a predetermined time, to charge, to replace, or neither to charge nor replace a battery, mounted in the autonomous vehicle 20, at a first point when the autonomous vehicle 20 located at the first point is to travel by the predetermined time to a second point that is a next destination.

In the present disclosure, the “predetermined time” includes, for example, a desired reception time of a recipient who is to receive a package, carried by the autonomous vehicle 20, at the second point. This example is not limiting, and the predetermined time may include any time that is a predetermined time before the desired reception time, for example. For example, the predetermined time includes the time to charge or replace the battery in the autonomous vehicle 20 at the second point. The predetermined time is not limited to a time associated with delivery of the package as described above and may include the time at which the autonomous vehicle 20 should travel to the second point for any other appropriate purpose.

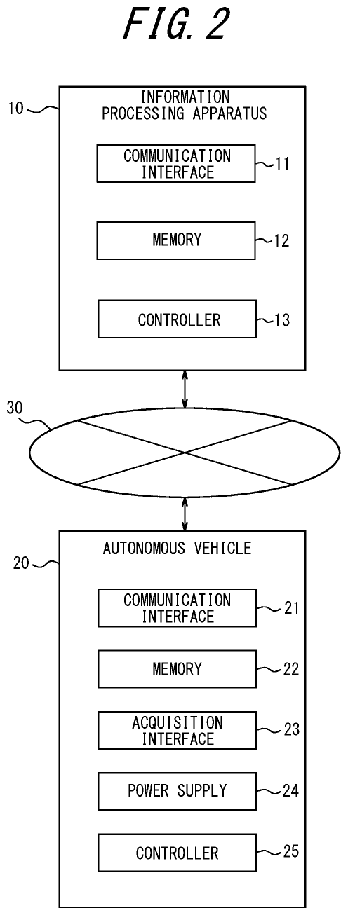

Next, with reference to FIG. 2, configurations of the information processing apparatus 10 and the autonomous vehicle 20 included in the information processing system 1 are primarily described. FIG. 2 is a functional block diagram illustrating schematic configurations of the information processing apparatus 10 and the autonomous vehicle 20 of FIG. 1.

As illustrated in FIG. 2, the information processing apparatus 10 includes a communication interface 11, a memory 12, and a controller 13.

The communication interface 11 includes a communication module that connects to the network 30. For example, the communication interface 11 may include a communication module compliant with mobile communication standards such as 4th Generation (4G) and 5th Generation (5G) or with Internet standards. In an embodiment, the information processing apparatus 10 is connected to the network 30 via the communication interface 11. The communication interface 11 transmits and receives various information via the network 30.

The memory 12 is, for example, a semiconductor memory, a magnetic memory, an optical memory, or the like, but is not limited to these. The memory 12 may, for example, function as a main memory, an auxiliary memory, or a cache memory. The memory 12 stores any information used for operations of the information processing apparatus 10. For example, the memory 12 may store a system program, an application program, various types of information received or transmitted by the communication interface 11, and the like. The information stored in the memory 12 may, for example, be updated with information received from the network 30 via the communication interface 11.

The controller 13 includes one or more processors. The “processor” in an embodiment is a general purpose processor or a dedicated processor that is dedicated to specific processing, but the processor is not limited to these. The controller 13 is communicably connected to each component forming the information processing apparatus 10 and controls operations of the information processing apparatus 10 overall.

Next, the configuration of the autonomous vehicle 20 included in the information processing system 1 is primarily described. As illustrated in FIG. 2, the autonomous vehicle 20 includes a communication interface 21, a memory 22, an acquisition interface 23, a power supply 24, and a controller 25.

The communication interface 21 includes a communication module that connects to the network 30. For example, the communication interface 21 may include a communication module compliant with mobile communication standards such as 4G and 5G. In an embodiment, the autonomous vehicle 20 is connected to the network 30 via the communication interface 21. The communication interface 21 transmits and receives various information via the network 30.

The memory 22 is, for example, a semiconductor memory, a magnetic memory, an optical memory, or the like, but is not limited to these. The memory 22 may, for example, function as a main memory, an auxiliary memory, or a cache memory. The memory 22 stores any information used for operations of the autonomous vehicle 20. For example, the memory 22 may store a system program, an application program, various types of information received or transmitted by the communication interface 21, and the like. The information stored in the memory 22 may, for example, be updated with information received from the network 30 via the communication interface 21.

The acquisition interface 23 includes one or more receivers compliant with any appropriate satellite positioning system. For example, the acquisition interface 23 may include a Global Positioning System (GPS) receiver. The acquisition interface 23 acquires the measured position of the autonomous vehicle 20 that travels between points as positional information. The acquisition interface 23 may acquire the positional information for the autonomous vehicle 20 continually, regularly, or non-regularly.

The power supply 24 includes a battery that enables the autonomous vehicle 20 to drive. Additionally, the power supply 24 includes any appropriate drive mechanism that enables charging or replacement of the battery based on control information from the information processing apparatus 10, described below. For example, the power supply 24 includes a drive mechanism for charging compatible with a battery charging facility provided at the point. For example, the power supply 24 includes a drive mechanism for replacement compatible with a battery replacement facility provided at the point.

The controller 25 includes one or more processors. The “processor” in an embodiment is a general purpose processor or a dedicated processor that is dedicated to specific processing, but the processor is not limited to these. The controller 25 is communicably connected to each component forming the autonomous vehicle 20 and controls operations of the autonomous vehicle 20 overall.

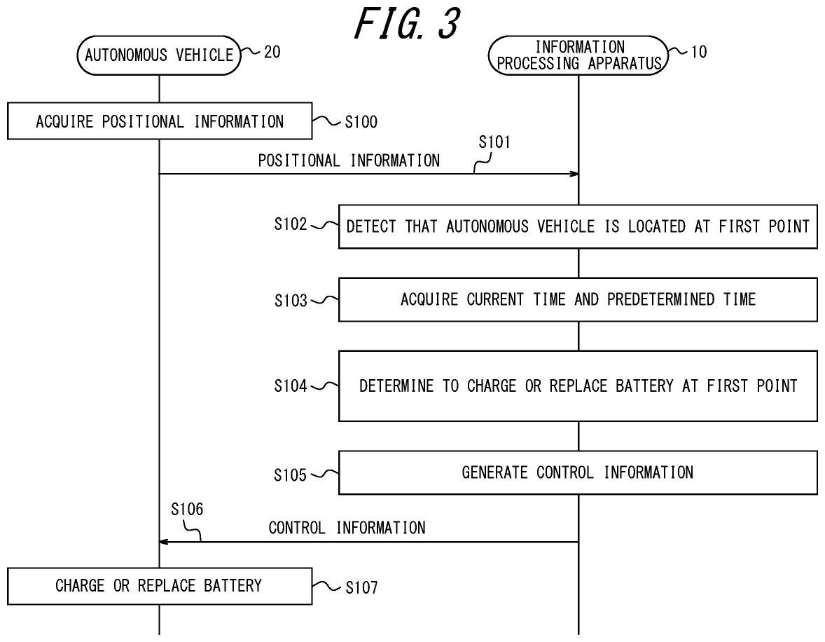

FIG. 3 is a sequence diagram for illustrating an example of an information processing method executed by the information processing system 1 of FIG. 1. With reference to FIG. 3, an example information processing method executed by the information processing system 1 of FIG. 1 is described. In the sequence diagram illustrated in FIG. 3, one autonomous vehicle 20 is assumed to arrive at the first point to charge or replace the battery included in the power supply 24.

In step S100, the controller 25 of the autonomous vehicle 20 uses the acquisition interface 23 to acquire the measured position of the autonomous vehicle 20 as positional information.

In step S101, the controller 25 of the autonomous vehicle 20 transmits the positional information acquired in step S100 to the information processing apparatus 10 via the communication interface 21 and the network 30.

In step S102, the controller 13 of the information processing apparatus 10 detects that the autonomous vehicle 20 is located at the first point based on the positional information acquired in step S101.

In step S103, the controller 13 of the information processing apparatus 10 acquires a predetermined time associated with the autonomous vehicle 20 detected in step S102, along with the current time.

In step S104, the controller 13 of the information processing apparatus 10 determines to charge or replace the battery mounted in the autonomous vehicle 20 at the first point based on the current time and the predetermined time acquired in step S103.

In step S105, the controller 13 of the information processing apparatus 10 generates control information for the autonomous vehicle 20 to charge or replace the battery at the first point based on the determination process in step S104.

In step S106, the controller 13 of the information processing apparatus 10 transmits the control information generated in step S105 to the autonomous vehicle 20 via the communication interface 11 and the network 30.

In step S107, the controller 25 of the autonomous vehicle 20 charges or replaces the battery included in the power supply 24 at the first point based on the control information acquired in step S106.

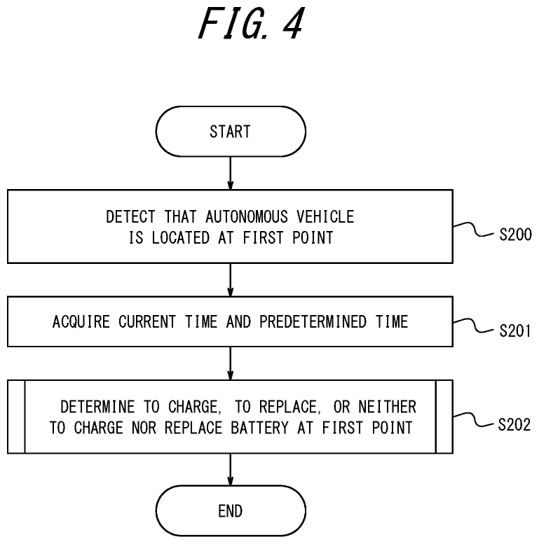

FIG. 4 is a flowchart illustrating a first example of an information processing method executed by the information processing apparatus 10 of FIG. 1. The flowchart in FIG. 4 illustrates the flow of basic processing of the information processing method executed by the information processing apparatus 10. In the flowchart illustrated in FIG. 4, it is assumed that the autonomous vehicle 20 located at the first point travels to the second point, which is the next destination, by the predetermined time.

In step S200, the controller 13 of the information processing apparatus 10 detects that the autonomous vehicle 20 is located at the first point based on positional information acquired from the autonomous vehicle 20.

In step S201, the controller 13 acquires the predetermined time associated with the autonomous vehicle 20 detected in step S200, along with the current time.

In step S202, the controller 13 determines to charge, to replace, or neither to charge nor replace the battery mounted in the autonomous vehicle 20 at the first point based on the current time and the predetermined time acquired in step S201.

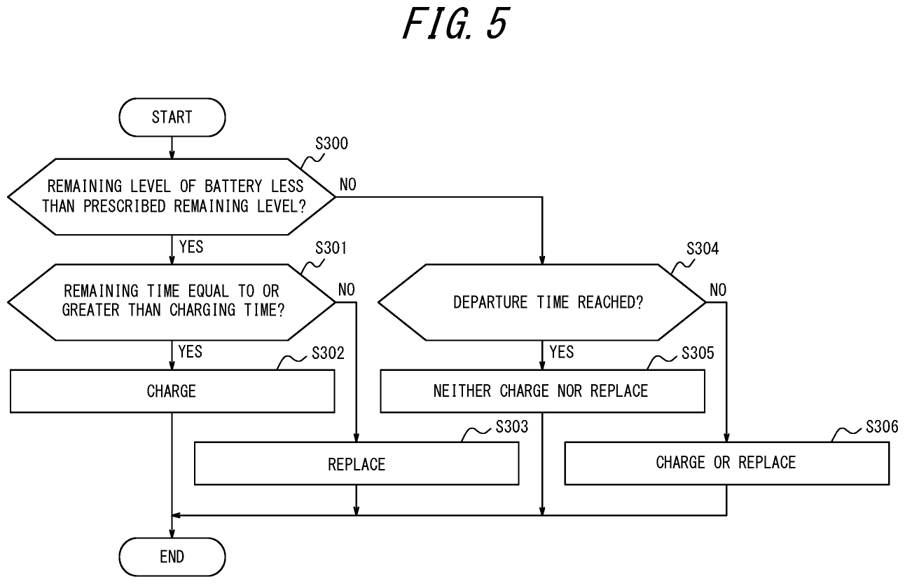

FIG. 5 is a flowchart illustrating a second example of an information processing method executed by the information processing apparatus 10 of FIG. 1. The flowchart in FIG. 5 more specifically illustrates the process of step S202 when the information processing apparatus 10 detects that only one autonomous vehicle 20 is located at the first point in step S200 of FIG. 4.

In step S300, the controller 13 of the information processing apparatus 10 judges whether the remaining level of the battery mounted in the one autonomous vehicle 20 detected in step S200 of FIG. 4 is less than a prescribed remaining level. When the controller 13 judges that the remaining level of the battery is less than the prescribed remaining level, the controller 13 executes the process of step S301. When the controller 13 judges that the remaining level of the battery is not less than the prescribed remaining level, i.e. that the remaining level of the battery is at least the prescribed remaining level, the controller 13 executes the process of step S304.

In the present disclosure, the “prescribed remaining level” includes, for example, the remaining level required to arrive at an N^{th} point, where a battery charging facility and/or a replacement facility is provided, when the autonomous vehicle 20 travels from the first point to at least one point that is a destination. For example, when a battery charging facility and/or a replacement facility is provided at the second point that is the next destination, the prescribed remaining level includes the remaining level required for the autonomous vehicle 20 to depart from the first point and arrive at the second point.

For example, the controller 13 may determine the prescribed remaining level of the battery based on topographical information along a travel route between the first point and the N^{th} point where the battery charging facility and/or the replacement facility is provided. In the present disclosure, the “topographical information” includes, for example, distance, the shape of undulations along the road surface, the average curvature of the road surface, the average surface μ of the road surface, and the like. For example, the controller 13 may determine the prescribed remaining level of the battery based on topographical information along a travel route between the first point and the second point, which is the next destination, when the battery charging facility and/or the replacement facility is provided at the second point.

For example, the controller 13 may determine a greater prescribed remaining level of the battery as the distance along the travel route between the first point and the second point is longer. For example, the controller 13 may determine a greater prescribed remaining level of the battery as the undulations of the road surface are rougher along the travel route between the first point and the second point. For example, the controller 13 may determine a greater prescribed remaining level of the battery as the average curvature of the road surface is larger along the travel route between the first point and the second point. For example, the controller 13 may determine a greater prescribed remaining level of the battery as the average surface μ of the road surface is smaller along the travel route between the first point and the second point.

In addition to or instead of such topographical information, the controller 13 may determine the prescribed remaining level of the battery based on load information on the load applied to the autonomous vehicle 20 in conjunction with driving, for example. In the present disclosure, the “load information” includes, for example, the weight of the packages to be delivered by the autonomous vehicle 20. For example, the controller 13 may determine a greater prescribed remaining level of the battery as the load information on the load applied to the autonomous vehicle 20 in conjunction with driving is larger.

When the controller 13 judges that the remaining level of the battery is less than the prescribed remaining level in step S300, the controller 13 compares, in step S301, the remaining time until the departure time at the first point, based on the predetermined time, with the charging time required to charge the battery to the prescribed remaining level.

In the present disclosure, the “departure time” includes, for example, a pre-planned time determined by the information processing apparatus 10 prior to travel of the autonomous vehicle 20 to the first point so that the autonomous vehicle 20 can arrive at the second point by the predetermined time. This example is not limiting, and the departure time may, for example, include a time calculated in real time by the information processing apparatus 10 after arrival of the autonomous vehicle 20 at the first point so that the autonomous vehicle 20 can arrive at the second point by the predetermined time.

The controller 13 judges whether the remaining time until the departure time at the first point is equal to or greater than the charging time required to charge the battery to the prescribed remaining level. When the controller 13 judges that the remaining time is equal to or greater than the charging time, the controller 13 executes the process of step S302. When the controller 13 judges that the remaining time is not equal to or greater than the charging time, i.e. that the remaining time is less than the charging time, the controller 13 executes the process of step S303.

In step S302, the controller 13 determines to charge the battery at the first point when judging in step S301 that the remaining time is equal to or greater than the charging time. The autonomous vehicle 20 thereby charges the battery of the power supply 24 to secure the prescribed remaining level of the battery before the departure time is reached.

In step S303, the controller 13 determines to replace the battery at the first point when judging in step S301 that the remaining time is less than the charging time. The autonomous vehicle 20 thereby immediately replaces the battery of the power supply 24 to secure the prescribed remaining level of the battery even if, for example, the remaining time until the departure time is brief.

When the controller 13 judges that the remaining level of the battery is at least the prescribed remaining level in step S300, the controller 13 judges, in step S304, whether the departure time at the first point, based on the predetermined time, has been reached. When the controller 13 judges that the departure time has been reached, the controller 13 executes the process of step S305. When the controller 13 judges that the departure time has not been reached, the controller 13 executes the process of step S306.

In step S305, the controller 13 determines neither to charge nor replace the battery at the first point when judging in step S304 that the departure time has been reached. The autonomous vehicle 20 thereby begins to travel toward the second point without the battery of the power supply 24 being charged or replaced at the first point.

In step S306, the controller 13 determines to charge or replace the battery at the first point when judging in step S304 that the departure time has not been reached. The battery of the power supply 24 in the autonomous vehicle 20 is thereby given an extra charge or is replaced to secure a remaining level sufficiently greater than the prescribed remaining level of the battery before the departure time is reached.

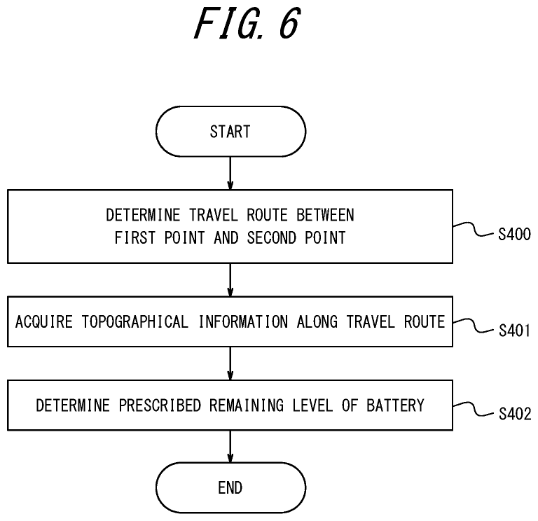

FIG. 6 is a flowchart illustrating a third example of an information processing method executed by the information processing apparatus 10 of FIG. 1. The flowchart in FIG. 6 illustrates the flow of basic processing, related to the determination of the prescribed remaining level of the battery, executed by the information processing apparatus 10.

In step S400, the controller 13 of the information processing apparatus 10 determines the travel route between the first point and the second point.

In step S401, the controller 13 acquires topographical information along the travel route determined in step S400.

In step S402, the controller 13 determines the prescribed remaining level of the battery based on the topographical information acquired in step S401.

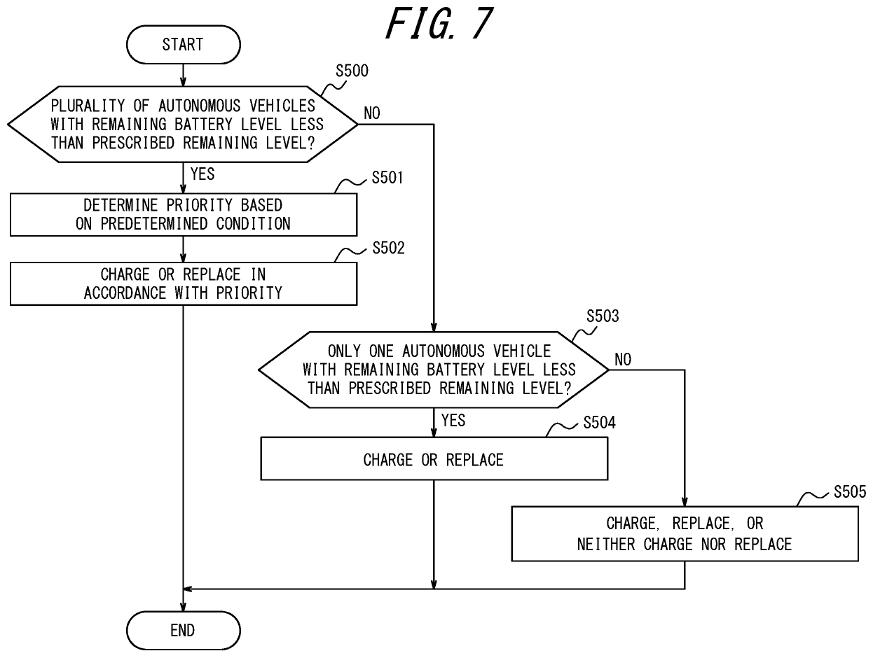

FIG. 7 is a flowchart illustrating a fourth example of an information processing method executed by the information processing apparatus 10 of FIG. 1. The flowchart in FIG. 7 more specifically illustrates the process of step S202 when the information processing apparatus 10 detects that a plurality of autonomous vehicles 20 is located at the first point in step S200 of FIG. 4.

In step S500, the controller 13 of the information processing apparatus 10 judges whether a plurality of autonomous vehicles 20 with a remaining level of the battery of less than the prescribed remaining level is located at the first point. When the controller 13 judges that a plurality of autonomous vehicles 20 with a remaining level of the battery of less than the prescribed remaining level is located at the first point, the controller 13 executes the process of step S501. When the controller 13 judges that a plurality of autonomous vehicles 20 with a remaining level of the battery of less than the prescribed remaining level is not located at the first point, i.e. that only one or zero is located at the first point, the controller 13 executes the process of step S503.

In step S501, the controller 13 determines a priority for charging or replacing the battery at the first point for each autonomous vehicle 20 based on a predetermined condition when judging that a plurality of autonomous vehicles 20 with a remaining level of the battery of less than the prescribed remaining level is located at the first point in step S500.

In the present disclosure, the “predetermined condition” includes, for example, whether a charging facility and a replacement facility for the battery are located at the second point associated with each autonomous vehicle 20. Alternatively or additionally, the predetermined condition may, for example, include the distance to the first point from the second point associated with each autonomous vehicle 20. The predetermined condition may, for example, include the remaining level of the battery at the current time for each autonomous vehicle 20. The predetermined condition may, for example, include the remaining time until the departure time associated with each autonomous vehicle 20.

In step S502, the controller 13 determines either to charge or to replace the battery, installed in the target autonomous vehicle 20, at the first point in accordance with the priority determined in step S501. At this time, the controller 13 may, for example, execute a process similar to steps S301 to S303 of FIG. 5 for the target autonomous vehicle 20.

When the controller 13 judges that a plurality of autonomous vehicles 20 with a remaining level of the battery of less than the prescribed remaining level is not located at the first point in step S500, the controller 13 judges in step S503 whether only one autonomous vehicle 20 with a remaining level of the battery of less than the prescribed remaining level is located at the first point. When the controller 13 judges that only one autonomous vehicle 20 with a remaining level of the battery of less than the prescribed remaining level is located at the first point, the controller 13 executes the process of step S504. When the controller 13 judges that there are no autonomous vehicles 20 with a remaining level of the battery of less than the prescribed remaining level located at the first point, the controller 13 executes the process of step S505.

When the controller 13 judges that only one autonomous vehicle 20 with a remaining level of the battery of less than the prescribed remaining level is located at the first point in step S503, the controller 13 determines, in step S504, either to charge or to replace the battery, installed in the autonomous vehicle 20, at the first point. At this time, the controller 13 may, for example, execute a process similar to steps S301 to S303 of FIG. 5 for the autonomous vehicle 20.

When the controller 13 judges that no autonomous vehicle 20 with a remaining level of the battery of less than the prescribed remaining level is located at the first point in step S503, the controller 13 determines, in step S505, to charge, to replace, or neither to charge nor replace the battery at the first point for at least one autonomous vehicle 20 among the plurality of autonomous vehicles 20 located at the first point. At this time, the controller 13 may, for example, execute a process similar to steps S304 to S306 of FIG. 5 for the autonomous vehicle 20 targeted by the determination.

For example, the controller 13 may determine the autonomous vehicle 20 that is the target of the process in step S505 based on the above-described predetermined condition. For example, the controller 13 may designate an autonomous vehicle 20 whose remaining time until the departure time is zero as the target of the process in step S505. At this time, the controller 13 may execute the process of steps S304 and S305 of FIG. 5 to determine neither to charge nor replace the battery at the first point. For example, the controller 13 may prioritize an autonomous vehicle 20 with a lower remaining level of the battery at the current time as the target of the process in step S505. At this time, the controller 13 may, for example, execute the process of steps S304 and S306 of FIG. 5 to determine either to charge or replace the battery at the first point. The battery of the power supply 24 in the autonomous vehicle 20 is thereby given an extra charge or is replaced to secure a remaining level sufficiently greater than the prescribed remaining level of the battery before the departure time is reached, even if the battery was at least the prescribed remaining level.

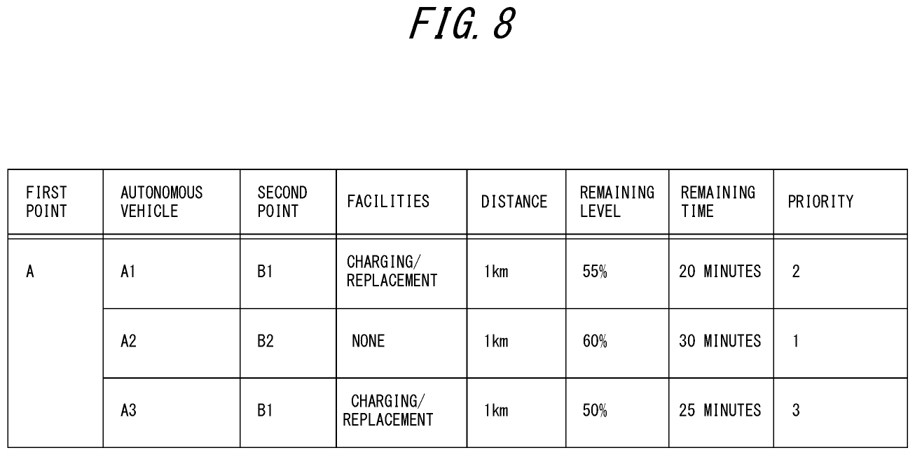

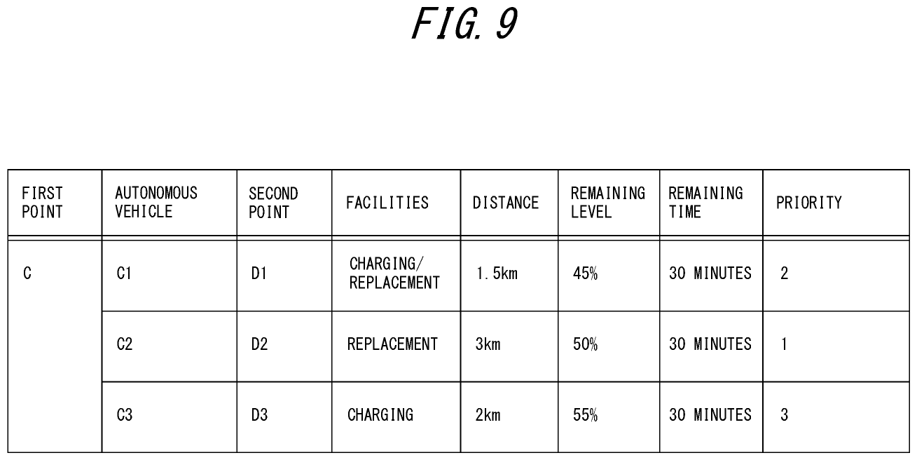

FIG. 8 is a diagram for illustrating a first example of processing by the controller 13 of the information processing apparatus 10 of FIG. 2. FIG. 9 is a diagram for illustrating a second example of processing by the controller 13 of the information processing apparatus 10 of FIG. 2. With reference to FIGS. 8 and 9, the process by the controller 13 for determining a priority for each autonomous vehicle 20 when a plurality of autonomous vehicles 20 with a remaining level of the battery of less than the prescribed remaining level are located at the first point is described in greater detail.

For the sake of explanation using FIGS. 8 and 9, it is assumed that while a predetermined autonomous vehicle 20 is using the charging facility or the replacement facility provided at the first point, the other autonomous vehicles 20 cannot use either of these facilities. In FIGS. 8 and 9, the number of autonomous vehicles with a remaining level of the battery of less than the prescribed remaining level is three for the sake of explanation, but this example is not limiting. The number of autonomous vehicles 20 with a remaining level of the battery of less than the prescribed remaining level may be two or may be four or more.

Referring to FIG. 8, autonomous vehicles A1, A2, and A3 are located at a first point A as autonomous vehicles 20 with a remaining level of the battery of less than the prescribed remaining level. The autonomous vehicle A1 located at the first point A travels to a second point B1, which is the next destination, by a predetermined time. The autonomous vehicle A2 located at the first point A travels to the second point B2, which is the next destination, by a predetermined time. The autonomous vehicle A3 located at the first point A travels to the second point B1, which is the next destination, by a predetermined time.

At the second point B1, both a battery charging facility and a replacement facility are provided. On the other hand, neither a battery charging facility nor a replacement facility is provided at the second point B2. The distance between the first point A and the second point B1 is 1 km. The distance between the first point A and the second point B2 is 1 km.

The remaining level of the battery of the autonomous vehicle A1 at the current time is 55%. The remaining level of the battery of the autonomous vehicle A2 at the current time is 60%. The remaining level of the battery of the autonomous vehicle A3 at the current time is 50%. The remaining time until the departure time of the autonomous vehicle A1 is 20 minutes. The remaining time until the departure time of the autonomous vehicle A2 is 30 minutes. The remaining time until the departure time of the autonomous vehicle A3 is 25 minutes.

Based on the above-described predetermined condition, the controller 13 determines priority 1 for the autonomous vehicle A2 as the priority for either charging or replacing the battery at the first point A, for example. For the autonomous vehicle A2, the remaining level of the battery at the current time is the highest and the remaining time until the departure time is also the longest. However, the controller 13 determines that charging or replacing the battery mounted in the autonomous vehicle A2 at the first point A is the highest priority, giving more weight to the condition that neither a battery charging facility nor a replacement facility is provided at the second point B2, which is the next destination.

Subsequently, the controller 13 determines priority 2 for the autonomous vehicle A1 as the priority for either charging or replacing the battery at the first point A, for example. In terms of only the autonomous vehicles A1 and A3, excluding the autonomous vehicle A2, the predetermined conditions for the facilities at the second point B1 are identical to each other. Similarly, the predetermined conditions for the distance from the first point A to the second point B1 are also identical to each other. On the other hand, the remaining level of the battery at the current time and the remaining time until the departure time each differ between the autonomous vehicle A1 and the autonomous vehicle A3. For example, the controller 13 determines that charging or replacing the battery mounted in the autonomous vehicle A1 at the first point A is the second priority, giving more weight to the condition that the remaining level of the battery at the current time is greater, but the remaining time until the departure time is shorter.

Finally, the controller 13 determines priority 3 for the autonomous vehicle A3 as the priority for either charging or replacing the battery at the first point A, for example.

Referring to FIG. 9, autonomous vehicles C1, C2, and C3 are located at a first point C as autonomous vehicles 20 with a remaining level of the battery of less than the prescribed remaining level. The autonomous vehicle C1 located at the first point C travels to the second point D1, which is the next destination, by a predetermined time. The autonomous vehicle C2 located at the first point C travels to the second point D2, which is the next destination, by a predetermined time. The autonomous vehicle C3 located at the first point C travels to the second point D3, which is the next destination, by a predetermined time.

At the second point D1, both a battery charging facility and a replacement facility are provided. At the second point D2, only a battery replacement facility is provided. At the second point D3, only a battery charging facility is provided. The distance between the first point C and the second point D1 is 1.5 km. The distance between the first point C and the second point D2 is 3 km. The distance between the first point C and the second point D3 is 2 km.

The remaining level of the battery of the autonomous vehicle C1 at the current time is 45%. The remaining level of the battery of the autonomous vehicle C2 at the current time is 50%. The remaining level of the battery of the autonomous vehicle C3 at the current time is 55%. The remaining time until the departure time of the autonomous vehicle C1 is 30 minutes. The remaining time until the departure time of the autonomous vehicle C2 is 30 minutes. The remaining time until the departure time of the autonomous vehicle C3 is 30 minutes.

Based on the above-described predetermined conditions, the controller 13 determines priority 1 for the autonomous vehicle C2 as the priority for either charging or replacing the battery at the first point C, for example. For the autonomous vehicles C1, C2, and C3, the predetermined conditions regarding the facilities at the second point are similar to each other, and the predetermined conditions regarding the remaining time until the departure time are identical to each other. However, the controller 13 determines that charging or replacing the battery mounted in the autonomous vehicle C2 at the first point C is the highest priority, giving more weight to the condition that the distance from the first point C to the second point D2, which is the next destination, is the longest.

Subsequently, the controller 13 determines priority 2 for the autonomous vehicle C1 as the priority for either charging or replacing the battery at the first point C, for example. In terms of only the autonomous vehicles C1 and C3, excluding the autonomous vehicle C2, the predetermined conditions for the facilities at the second point are similar to each other. The predetermined conditions regarding the remaining time until the departure time are identical to each other. On the other hand, the distance from the first point C to the second point and the remaining level of the battery at the current time are each differ between the autonomous vehicle C1 and the autonomous vehicle C3. For example, the controller 13 determines that charging or replacing the battery mounted in the autonomous vehicle C1 at the first point C is the second priority, giving more weight to the condition that the distance from the first point C to the second point is shorter, but the remaining level of the battery at the current time is lower.

Finally, the controller 13 determines priority 3 for the autonomous vehicle C3 as the priority for either charging or replacing the battery at the first point C, for example. As described above, the controller 13 flexibly determines the priority for a plurality of autonomous vehicles 20 that are located at the first point and have a remaining level of the battery of less than a predetermined amount by, for example, comprehensively comparing predetermined conditions that include a plurality of items.

According to the above embodiment, an electricity shortage in an autonomous vehicle 20 that travels between points can be prevented. For example, by determining, based on the current time and the predetermined time, to charge, to replace, or neither to charge nor replace the battery mounted in the autonomous vehicle 20 at the first point, the information processing apparatus 10 can determine to charge the battery mounted in the autonomous vehicle 20 to increase the remaining level of the battery when there is extra time until the predetermined time. For example, the information processing apparatus 10 can determine to replace the battery mounted in the autonomous vehicle 20 so that the battery can immediately be replaced with a charged battery when there is not much time left until the predetermined time. On the other hand, the information processing apparatus 10 can determine neither to charge nor to replace the battery when there is not much time left until the predetermined time if, for example, the remaining level of the battery is at least a prescribed remaining level. Departure of the autonomous vehicle 20 can thus be prioritized.

The information processing apparatus 10 determines whether to charge or to replace the battery at the first point by comparing the remaining time until the departure time with the charging time. For example, the information processing apparatus 10 can determine to charge the battery mounted in the autonomous vehicle 20 to increase the remaining level of the battery when the remaining time until the departure time is longer than the charging time. For example, the information processing apparatus 10 can determine to replace the battery mounted in the autonomous vehicle 20 so that the battery can immediately be replaced with a charged battery when the remaining time until the departure time is shorter than the charging time. In this way, even when the charging time for charging the mounted battery to a prescribed remaining level cannot be secured for the autonomous vehicle 20 at the first point, the battery can be replaced by a battery with at least the prescribed remaining level, preventing an electricity shortage during travel between points.

By determining the prescribed remaining level of the battery based on topographical information along the travel route between the first point and the second point, the information processing apparatus 10 can accurately determine the prescribed remaining level of the battery necessary for travel between points. In this way, the information processing apparatus 10 can accurately execute this determination process in the case, for example, of using the prescribed remaining level of the battery as one judgment criterion when determining to charge, to replace, or neither to charge nor replace the battery at the first point. Consequently, the autonomous vehicle 20 can more reliably prevent an electricity shortage during travel between points.

By the predetermined time including a desired reception time of a recipient who is to receive a package, carried by the autonomous vehicle, at the second point, the autonomous vehicle 20 can reliably deliver a package by the predetermined time to the recipient at the second point while preventing an electricity shortage during travel between the first point and the second point. The reliability of an autonomous delivery system for packages that incorporates the autonomous vehicle 20 thereby improves, and the convenience for users of the autonomous delivery system, including the recipient, improves.

The information processing apparatus 10 determines a priority for each autonomous vehicle 20 based on a predetermined condition. Consequently, even when there is a plurality of autonomous vehicles that are located at the first point and have a remaining level of the battery of less than the prescribed remaining level, the information processing apparatus 10 can determine to charge or to replace the battery at the first point in an appropriate order for the autonomous vehicles 20. Regular operation of a plurality of autonomous vehicles 20 at the first point with regard to battery charging or replacement can thus be achieved. Consequently, the information processing apparatus 10 can appropriately manage the batteries and the schedule of a plurality of autonomous vehicles 20 located at the first point. The information processing apparatus 10 can thereby appropriately manage the schedule of the autonomous vehicles 20 while preventing an electricity shortage in the autonomous vehicles 20 even after departure from the first point.

The predetermined condition includes whether a charging facility and a replacement facility for the battery are located at the second point associated with each autonomous vehicle 20. The information processing apparatus 10 can thereby determine to charge or to replace the battery at the first point on a priority basis for an autonomous vehicle 20 associated with a second point where, for example, neither a battery charging facility nor a replacement facility is provided. The battery can reliably be charged or replaced at the first point for such an autonomous vehicle 20. Hence, even when neither a battery charging facility nor a replacement facility is provided at the second point, an electricity shortage can also be prevented during travel between points after departure from the second point.

By the autonomous vehicle 20 including a small, unmanned delivery vehicle configured to deliver packages autonomously, the information processing system 1 can function as an autonomous delivery system for packages using the autonomous vehicle 20. The information processing system 1 can reliably deliver a package to a recipient by the predetermined time while suppressing an electricity shortage in the autonomous vehicle 20 that travels between points. The reliability of the information processing system 1 thereby improves, and the convenience for users, including the recipient, improves.

While the present disclosure has been described based on the drawings and examples, it should be noted that various changes and modifications may be made by those skilled in the art based on the present disclosure. Accordingly, such modifications and revisions are included within the scope of the present disclosure. For example, the functions and the like included in each component, step, or the like can be rearranged in a logically consistent manner. A plurality of components, steps, or the like may be combined into one, or a single component, step, or the like may be divided.

For example, at least some of the processing operations performed in the information processing apparatus 10 in the above embodiment may be performed in the autonomous vehicle 20. For example, instead of the information processing apparatus 10, the autonomous vehicle 20 itself may perform the processing operations described above with respect to the information processing apparatus 10. At least a portion of the processing operations performed in the autonomous vehicle 20 may be performed in the information processing apparatus 10.

For example, a general purpose electronic device, such as a smartphone or a computer, can also be configured to function as the information processing apparatus 10 according to the above embodiment. Specifically, a program describing the processing content for realizing the functions of the information processing apparatus 10 and the like according to the embodiment is stored in a memory of the electronic device, and the program is read and executed by the processor of the electronic device. Accordingly, the present disclosure can also be embodied as a program executable by a processor.

Alternatively, an embodiment of the present disclosure may be implemented as a non-transitory computer readable medium that stores a program executable by one or more processors to cause the information processing apparatus 10 according to the embodiment or the like to perform the various functions. It is to be understood that these embodiments are also included within the scope of the present disclosure.

For example, the information processing apparatus 10 in the above embodiment may be mounted in the autonomous vehicle 20. At this time, the information processing apparatus 10 may communicate information directly with the autonomous vehicle 20 without passing through the network 30.

In the above embodiment, the information processing apparatus 10 has been described as using the predetermined remaining amount of the battery as one judgment criterion when determining to charge, to replace, or neither to charge nor replace the battery at the first point, but this example is not limiting. The information processing apparatus 10 need not use the predetermined remaining amount of the battery as a judgment criterion. In other words, the information processing apparatus 10 may omit the process of step S300 in FIG. 5, for example, and determine to charge, to replace, or neither to charge nor replace the battery at the first point based on the current time and the predetermined time.

In the above embodiment, the information processing apparatus 10 has been described as determining whether to charge or to replace the battery at the first point by comparing the remaining time until the departure time with the charging time, but this example is not limiting. For example, instead of using the charging time, which changes for each battery, as a threshold, the information processing apparatus 10 may use any other constant threshold and compare the threshold with the remaining time until the departure time to determine whether to charge or to replace the battery at the first point.

In the above embodiment, the information processing apparatus 10 has been described as determining a priority for each autonomous vehicle 20 based on a predetermined condition, but this example is not limiting. The information processing apparatus 10 need not determine such priority. For example, as long as the schedule of each autonomous vehicle 20 among a plurality of autonomous vehicles 20 located at the first point can be managed accurately, the information processing apparatus 10 may determine whether to charge or to replace the battery of the autonomous vehicle 20 in the order of arrival at the first point.

In the above embodiment, the information processing apparatus 10 has been described as determining the priority while comprehensively comparing predetermined conditions that include a plurality of items, but this example is not limiting. The information processing apparatus 10 may determine the priority based on at least one item among the aforementioned plurality of items included in the predetermined conditions.

1. An information processing apparatus for controlling at least one autonomous vehicle that travels between points, the information processing apparatus comprising a controller configured to:
determine, based on a current time and a predetermined time, to charge, to replace, or neither to charge nor replace a battery, mounted in the autonomous vehicle, at a first point when the autonomous vehicle located at the first point is to travel by the predetermined time to a second point that is a next destination.

2. The information processing apparatus of claim 1, wherein the controller is configured to determine to charge or to replace the battery at the first point by comparing a remaining time until a departure time at the first point based on the predetermined time with a charging time required to charge the battery to a prescribed remaining level.

3. The information processing apparatus of claim 2, wherein the controller is configured to determine the prescribed remaining level of the battery based on topographical information along a travel route between the first point and the second point.

4. The information processing apparatus of claim 1, wherein the predetermined time includes a desired reception time of a recipient who is to receive a package, carried by the autonomous vehicle, at the second point.

5. The information processing apparatus of claim 1, wherein the at least one autonomous vehicle includes a plurality of autonomous vehicles, and when the controller judges that the plurality of autonomous vehicles have a remaining level of the battery of less than a prescribed remaining level and are located at the first point, the controller is configured to determine a priority for charging or replacing the battery at the first point for each autonomous vehicle among the plurality of autonomous vehicles based on a predetermined condition.

6. The information processing apparatus of claim 5, wherein the predetermined condition includes whether a charging facility and replacement facility for the battery are located at the second point associated with each autonomous vehicle.

7. The information processing apparatus of claim 1, wherein the autonomous vehicle includes a small, unmanned delivery vehicle configured to deliver packages autonomously.

8. An information processing system comprising:
the information processing apparatus of claim 1; and
the autonomous vehicle controlled by the information processing apparatus.

9. A non-transitory computer readable medium storing a program executable by one or more processors and configured to cause an information processing apparatus for controlling at least one autonomous vehicle that travels between points to execute functions comprising:
determining, based on a current time and a predetermined time, to charge, to replace, or neither to charge nor replace a battery, mounted in the autonomous vehicle, at a first point when the autonomous vehicle located at the first point is to travel by the predetermined time to a second point that is a next destination.

10. The non-transitory computer readable medium of claim 9, wherein the functions include determining to charge or to replace the battery at the first point by comparing a remaining time until a departure time at the first point based on the predetermined time with a charging time required to charge the battery to a prescribed remaining level.

11. The non-transitory computer readable medium of claim 10, wherein the functions include determining the prescribed remaining level of the battery based on topographical information along a travel route between the first point and the second point.

12. The non-transitory computer readable medium of claim 9, wherein the predetermined time includes a desired reception time of a recipient who is to receive a package, carried by the autonomous vehicle, at the second point.

13. The non-transitory computer readable medium of claim 9, wherein the at least one autonomous vehicle includes a plurality of autonomous vehicles, and the functions include determining, when it is judged that the plurality of autonomous vehicles have a remaining level of the battery of less than a prescribed remaining level and are located at the first point, a priority for charging or replacing the battery at the first point for each autonomous vehicle among the plurality of autonomous vehicles based on a predetermined condition.

14. The non-transitory computer readable medium of claim 13, wherein the predetermined condition includes whether a charging facility and replacement facility for the battery are located at the second point associated with each autonomous vehicle.

15. An autonomous vehicle to be controlled by an information processing apparatus and to travel between points, the autonomous vehicle comprising a controller configured to:
determine, based on a current time and a predetermined time, to charge, to replace, or neither to charge nor replace a mounted battery at a first point when the autonomous vehicle is to travel by the predetermined time to a second point that is a next destination.

16. The autonomous vehicle of claim 15, wherein the controller is configured to determine to charge or to replace the battery at the first point by comparing a remaining time until a departure time at the first point based on the predetermined time with a charging time required to charge the battery to a prescribed remaining level.

17. The autonomous vehicle of claim 16, wherein the controller is configured to determine the prescribed remaining level of the battery based on topographical information along a travel route between the first point and the second point.

18. The autonomous vehicle of claim 15, wherein the predetermined time includes a desired reception time of a recipient who is to receive a package, carried by the autonomous vehicle, at the second point.

19. The autonomous vehicle of claim 15, wherein when the controller judges that the autonomous vehicle and one or more other autonomous vehicles have a remaining level of the battery of less than a prescribed remaining level and are located at the first point, the controller is configured to determine a priority for charging or replacing the battery at the first point for the autonomous vehicle and each other autonomous vehicle based on a predetermined condition.

20. The autonomous vehicle of claim 19, wherein the predetermined condition includes whether a charging facility and replacement facility for the battery are located at the second point associated with the autonomous vehicle and each other autonomous vehicle.
